(19) United States
(12) Patent Application Publication
(10) Pub. No.: US 2025/0203878 A1
(43) Pub. Date: Jun. 19, 2025

(54) ELECTROFORMED ENERGY-EFFICIENT PHASE CHANGE MEMORY DEVICE WITH THIN ACTIVE REGION

(71) Applicant: International Business Machines Corporation, Armonk, NY (US)

(72) Inventors: Timothy Mathew Philip, Albany, NY (US); Abu Sebastian, Adliswil (CH); Kevin W. Brew, Niskayuna, NY (US); Ghazi Sarwat Syed, Kilchberg (CH); JIN PING HAN, Yorktown Heights, NY (US); Benedikt Kersting, Lüdinghausen (DE); Vara Sudananda Prasad Jonnalagadda, Wallisellen (CH); Ching-Tzu Chen, Ossining, NY (US)

(21) Appl. No.: 18/541,444

(22) Filed: Dec. 15, 2023

(51) Int. Cl. H10B 63/10; H10N 70/00; H10N 70/20

(52) U.S. Cl. CPC H10B 63/10; H10N 70/021; H10N 70/235; H10N 70/8413; H10N 70/8828

(57) ABSTRACT

A memory structure and corresponding method of making and operating that includes: a first electrode; a first phase change material (PCM) layer comprising a first PCM positioned above the first electrode; a second PCM layer comprising a second PCM located above the first PCM layer, wherein the second PCM is compositionally different than the first PCM and has at least one of: a higher crystallization temperature than the first PCM, a longer crystallization time than the first PCM, and/or more easily forms a void than the first PCM; a barrier layer positioned in between the first PCM layer and the second PCM layer to inhibit intermixing of the first PCM and the second PCM layer; and a second electrode positioned above the second PCM layer. The PCM memory structure can further include an insulating and/or resistive region formed above the barrier layer in the second PCM layer.

### BACKGROUND

The present application relates to a memory structure, and more particularly to a phase change material (PCM) memory structure, its method of manufacture, and its operation.

Phase change materials (PCMs) have been pursued for a variety of applications such as, for example, storage class memory as well as storing weights of neural networks for artificial intelligence. In typical PCMs formed as memory structures, the amount of PCM to melt and change phase can be relatively large requiring one or more high and/or long current pulses to melt the appropriate amount of PCM. This high and/or longer current duration can consume relatively large amounts of energy and use relatively large amounts of power. It is highly desirable to increase the PCM energy efficiency and decrease the amount of power consumed by the PCM memory device.

In addition, memory structures utilizing PCM have resulted in poor contact between a top or second electrode and the PCM, including where the electrode contacts the PCM. This poor contact has resulted in reliability issues for memory structures using PCMs. It is highly desirable to increase the reliability of PCM memory structures.

### SUMMARY

A PCM memory structure is provided. In one aspect of the present disclosure one or more memory structures, preferably phase change material (PCM) memory structures, their method of manufacture, and their operation are disclosed. In one embodiment, the (PCM) memory structure includes a plurality of phase change material (PCM) element-containing structures stacked one atop the other. In an embodiment, the (PCM) memory structure includes, from bottom to top, at least one bottom electrode (e.g., a heater electrode), a plurality of phase change material (PCM) elements and/or layers, and a top electrode. In a further arrangement, the plurality of phase change material (PCM) elements and/or layers are separated by a barrier layer to inhibit intermixing of compositionally different PCMs forming phase change material (PCM) elements and/or layers.

In one or more embodiments a PCM memory structure is described that includes: a first electrode; a first phase change material (PCM) layer comprising a first PCM, the first PCM layer positioned above the first electrode; a second PCM layer located above the first PCM layer, the second PCM layer comprising a second PCM wherein the second PCM is compositionally different than the first PCM and has a properties group consisting of at least one of: a higher crystallization temperature than the first PCM, a longer crystallization time than the first PCM, more easily forms a void than the first PCM, and combinations thereof; a barrier layer positioned in between the first PCM layer and the second PCM layer wherein the barrier layer inhibits intermixing of the first PCM layer and the second PCM layer; and a second electrode positioned above the second PCM layer.

The PCM memory structure in an arrangement can further include an electrically insulating and/or resistive region formed above the barrier layer in the second PCM layer, where in an approach the electrically insulating and/or resistive region is formed electrically or through process conditions. The electrically insulating and/or resistive region in an embodiment is a hollow region and/or void. The electrically insulating and/or resistive region preferably is dome shaped.

Also disclosed is a method of making a PCM memory structure that includes: providing a first electrode; providing a first phase change material (PCM) layer comprising a first PCM, the first PCM layer positioned above the first electrode; providing a second PCM layer located above the first PCM layer, the second PCM layer comprising a second PCM wherein the second PCM is compositionally different than the first PCM and has a properties group consisting of at least one of: a higher crystallization temperature than the first PCM, a longer crystallization time than the first PCM, more easily forms a void than the first PCM, and combinations thereof; a barrier layer positioned in between the first PCM layer and the second PCM layer wherein the barrier layer inhibits intermixing of the first PCM layer and the second PCM layer; and providing a second electrode positioned above the second PCM layer. In one or more arrangements the method of making the PCM memory structure includes forming an electrically insulating and/or resistive region above the barrier layer in the second PCM layer, where in an approach the electrically insulating and/or resistive region is formed electrically or through process conditions. In one or more arrangements the method of making the PCM memory structure includes forming a hollow region or void as the electrically insulating and/or resistive region above the barrier layer in the second PCM layer, where in an approach the hollow region or void is formed electrically or through process conditions. The electrically insulating and/or resistive region preferably is dome shaped.

A method of operating a PCM memory structure is also described where the method includes: applying, in an initial state of a phase change material (PCM) memory structure comprising a first PCM layer comprising a first PCM in a crystalline and/or electrically conductive state, a second PCM layer formed of a compositionally different PCM, and a barrier layer positioned between the first PCM layer and the second PCM layer, a forming current to create an electrically insulating and/or resistive region in the second PCM layer to create a formed PCM memory structure. The method of operating the PCM memory structure can further include applying to the formed PCM memory structure a RESET melting current pulse that melts only a first portion of the first PCM in the first PCM layer, and in a further approach further includes cooling the melted first portion of the first PCM in the first PCM layer to form an amorphous and/or electrically resistive and/or insulating first PCM portion in first PCM layer to create a RESET PCM memory structure. The method of operating the PCM memory structure in an embodiment can further include applying to the RESET PCM memory structure a SET melting current pulse that remelts the amorphous and/or electrically resistive and/or insulating first PCM portion in the first PCM layer, and in a further embodiment further includes cooling the remelted first PCM portion of the first PCM layer to form a crystalline electrically conductive first PCM portion in the first PCM layer to create a SET PCM memory structure.

The foregoing and other objects, features and advantages of the invention will be apparent from the following more particular descriptions of exemplary embodiments of the invention as illustrated in the accompanying drawings.

### BRIEF DESCRIPTION OF THE DRAWINGS

The various aspects, features, and embodiments of PCM memory structures; methods or techniques for making PCM memory structures; and/or the operation and function of PCM memory structures will be better understood when read in conjunction with the figures provided. It may be noted that a numbered element in the figures is typically numbered according to the figure in which the element is introduced, is typically referred to by that number throughout succeeding figures, and that like reference numbers generally represent like parts of exemplary embodiments of the invention.

Embodiments are provided in the figures for the purpose of illustrating aspects, features, and/or various embodiments of the memory structure, e.g., PCM memory structure; methods and techniques for making the memory structure, and/or the operation and function of the memory structure, but the claims should not be limited to the precise arrangement, structures, layers, features, materials, aspects, assemblies, subassemblies, functional units, embodiments, methods, processes, or devices shown. The arrangements, structures, layers, features, materials, aspects, assemblies, subassemblies, functional units, embodiments, methods, processes, and/or devices shown may be used singularly or in combination with other arrangements, structures, layers, features, materials, aspects, assemblies, subassemblies, functional units, methods, processes, and/or devices.

FIG. 1 is a cross-sectional view of an exemplary structure that can be employed as a PCM memory device that includes a bottom electrode layer, PCM material, and a top electrode layer forming the PCM memory device structure.

FIG. 2 is a cross-sectional view of an exemplary structure that can be employed in accordance with an embodiment of the present application, the exemplary structure including a bottom electrode structure, at least two PCM-containing material layers separated by a barrier layer, and a top electrode structure creating a formed PCM memory structure (in the SET state).

FIG. 3 is a cross-sectional view of the exemplary structure shown in FIG. 2 with the bottom electrode structure, the at least two PCM-containing material layers separated by the barrier layer, and the top electrode structure creating the formed PCM memory structure (in the RESET state).

FIG. 4 is a cross-sectional view of another exemplary structure that can be employed in accordance with an embodiment of the present application, the exemplary structure including a bottom electrode structure, at least two PCM-containing material layers separated by a barrier layer, and a top electrode structure creating a formed PCM memory structure (in a SET state).

FIG. 5 is a cross-sectional view of the exemplary structure shown in FIG. 4 with the bottom electrode structure, the at least two PCM-containing material layers separated by the barrier layer, and the top electrode structure creating the formed PCM memory structure (in a RESET state).

FIG. 6 is a cross-sectional view of yet another exemplary structure that can be employed in accordance with an embodiment of the present application, the exemplary structure including a bottom electrode structure, a projection liner layer, at least two PCM-containing material layers separated by a barrier layer, and a top electrode structure creating a formed memory structure (in a SET state).

FIG. 7 is a cross-sectional view of the exemplary structure shown in FIG. 6 with the bottom electrode structure, the protective liner layer, the at least two PCM-containing material layers separated by the barrier layer, and the top electrode structure creating the formed PCM memory structure in a RESET state.

FIG. 8 is an exemplary flow chart of a method of forming PCM memory structures according to one or more embodiments of the present application.

FIG. 9 illustrates a cross-sectional view of an exemplary bottom layer that includes an electrode structure in a substrate during formation of a PCM memory structure according to an embodiment of the present application.

FIG. 10 illustrates a cross-sectional view of an exemplary first PCM layer, a barrier layer, a second and/or top PCM layer, and the top electrode structure and/or layer during formation of a PCM memory structure according to an embodiment of the present application.

FIG. 11 illustrates a cross-sectional view of an exemplary PCM memory cell sub-structure after an etching process during formation of a PCM memory structure according to an embodiment of the present application.

FIG. 12 illustrates a cross-sectional view of the exemplary PCM memory cell sub-structure of FIG. 11 after encapsulation during formation of a PCM memory structure according to an embodiment of the present application.

FIG. 13 illustrates a cross-sectional view of the exemplary PCM memory cell sub-structure of FIG. 12 after formation of top contact during formation of a PCM memory structure according to an embodiment of the present application.

FIG. 14 illustrates a cross-sectional view of an exemplary PCM memory structure during the electrical forming operation of a PCM memory structure according to an embodiment of the present application.

FIG. 15 illustrates a cross-sectional view of an exemplary of the PCM memory structure after the electrical forming operation and/or in the SET state according to an embodiment of the present application.

FIG. 16 illustrates a cross-sectional view of the exemplary PCM memory structure of FIG. 15 in the RESET state.

FIG. 17 is a cross-sectional view of the exemplary structure of PCM memory device of FIG. 16 in its RESET state with a pulse being applied to the PCM memory structure.

FIG. 18 is an exemplary flow chart of a method of operating PCM memory structures according to an embodiment of the present application.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. In addition, features described herein can be used in combination with other described features in each of the various possible combinations and permutations. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

Unless otherwise specifically defined herein, all terms are to be given their broadest possible interpretation including meanings implied from the specification as well as meanings understood by those skilled in the art and/or as defined in dictionaries, treatises, etc. It should also be noted that, as used in the specification and the appended claims, the singular forms “a”, “an” and “the” include plural referents unless otherwise specified, and that the terms “includes”, “comprises”, and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath”, “directly under”, or “in contact with” another element, there are no intervening elements present.

The disclosure is directed to an energy efficient phase change material (PCM) memory structure and/or device, preferably electroformed PCM memory structure and/or device, with a thin active region that uses less energy and consumes less power while providing enhanced reliability. Phase change materials (PCMs) have been proposed for memory devices to store electronic data. PCMs are typically electrically conductive when in the crystalline state and electrically resistive and/or insulating when in the amorphous state. On the other hand, inverse PCMs are electrically conductive in the amorphous state and electrically resistive in the crystalline state. In one or more embodiments, the PCM memory structure and/or device has an electrode, preferably a heater electrode, through which current flows as appropriate to heat and melt the PCM material and/or by controlling the cooling conditions (e.g., cooling time) of the melted PCM provides either an electrically resistive PCM or an electrically conductive PCM, more specifically an electrically insulating and/or resistive region in a PCM layer. Controlling the insulating nature of and/or the resistivity of one or more PCMs permits the formation of a

PCM memory cell structure as further described in the present application. It should be appreciated that in instances the terms electrically insulating, resistive, and conductive are relative terms and will depend on adjacent materials and/or structures in the device, apparatus, and/or device.

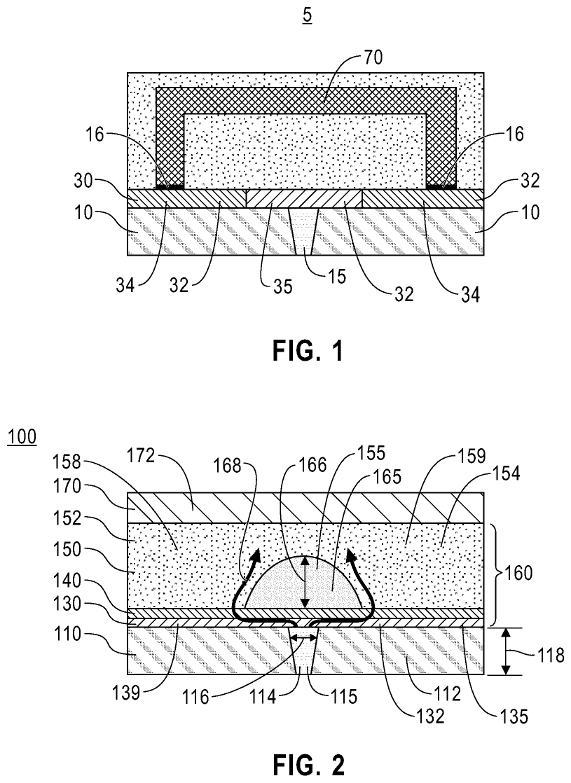

FIG. 1 illustrates a memory device 5 utilizing phase change material (PCM) 32 where large amounts of the phase change material (PCM) 32 have to be heated by the heater electrode 15 to melt and/or permit the PCM 32 to undergo a phase change. More specifically, PCM layer 30, containing PCM 32, is relatively thick and region 35 of PCM layer 30 is subject to an electrical forming operation in the form of current that heats the PCM 32 in PCM layer 30 to melt and by controlling the cooling conditions of region 35 the phase of region 35 changes so that it is different than the phase of regions 34 in PCM layer 30. Heating a large volume of PCM 32 (e.g., the relatively thick layer 30 of PCM 32) to melt the PCM 32 in region 35 to permit a phase change requires a large amount of energy and is not particularly energy efficient.

In addition, in FIG. 1 there is poor contact in PCM memory device 5 between the top electrode 70 and PCM material 32 in regions 34 from the electrode etch. In other words, there could be etch damage from the PCM etch between the electrode 70 and the PCM material 32 as illustrated at regions 16. This poor contact region 16 and etch damage can cause reliability issues with PCM memory device 5. The present disclosure is directed to a PCM memory structure and/or device that is more energy efficient and also potentially provides enhanced reliability over prior art PCM memory devices.

The present disclosure provides a structure and method to form a PCM memory structure and/or device that has a unique material and/or structural combination, and ensures good contact between the PCM and the second, top, and/or outer electrode. In addition, in one or more embodiments, no additional masks are required to form the second, top, and/or outer electrode. The present disclosure in an embodiment is directed to a tri-layer PCM device that effectively creates a PCM memory structure and/or cell by forming, preferably electrically forming, an electrically insulating and/or electrically resistive region above an active PCM region that changes between an electrically conductive and an electrically insulating and/or resistive state.

The structure and method in an approach includes providing, positioning, applying, and/or depositing a first, bottom, and/or inner PCM material in a first, bottom, and/or inner PCM layer that will be the active region over the (e.g., heater) electrode (and substrate) and providing, positioning, applying, and/or depositing a second, top, and/or outer PCM in a second PCM layer over the (e.g., heater) electrode (and substrate) and the first PCM layer. The first PCM material in the first, bottom, and/or inner PCM layer in an embodiment is formed of a compositionally different PCM than the second PCM in the second, top, and/or outer PCM layer, and in an arrangement the first PCM has a crystalline temperature that is lower than the crystalline temperature of the second PCM. In an approach the first PCM in the first PCM layer has a crystallization temperature (Tc) that is lower than the crystallization temperature (Tc) of the second PCM in the second PCM layer, for example, by 50 degrees C. or more. In an illustrative embodiment the first PCM has a low crystalline temperature (low Tc), preferably about 150-180 degrees C. The first, bottom, and/or inner PCM layer preferably is applied where it is in a conductive state, and in approach is in a crystalline state. The first PCM layer in an embodiment is preferably thin, preferably 15 nm thick or less, although other values for the thickness of first PCM layer are contemplated.

The structure and method further includes providing, positioning, applying and/or depositing a barrier layer adjacent to, over, directly over, above, on top of, and/or in contact with the first PCM layer that preferably inhibits and/or prevents intermixing between the at least two compositionally different PCM materials in the first and second PCM layers, where the barrier layer in an embodiment is conductive and/or semiconductive and preferably has similar or less electrical resistance than the first PCM layer in its electrically conductive state. In an embodiment, the barrier layer creates additional thermal boundary resistance to better contain heat in first PCM layer and/or help localized heating. The barrier layer in a further embodiment can increase the forming voltage and/or reduce the required write current than if the barrier layer was not present. The barrier layer in an approach is a thin non-phase change material with high in-plane resistivity, and in yet a further approach is a thin non-phase change metal with high in-plane resistivity. In an approach, the barrier layer is thinner than the first PCM layer and/or the second PCM layer, and in a further arrangement is preferably 2 nm to 8 nm thick, although other thickness values are contemplated.

The structure and method in an embodiment further includes providing, positioning, applying, and/or depositing a second, top, and/or outer PCM layer adjacent to, over, directly over, on top of, and/or in contact with the barrier layer. The second, top, and/or outer PCM layer preferably is formed of a compositionally different PCM material than the PCM forming the first, bottom, and/or inner PCM material, where in an approach the second, top, and/or outer PCM layer uses an inverse PCM (iPCM) layer adjacent to, over, directly over, above, on top of, and/or in contact with the barrier layer. The second, top, and/or outer PCM layer preferably is relatively thick compared to the first, bottom, and/or inner PCM layer, preferably greater than 30 nm, more preferably about 60 nm or greater, although other thickness values for the second, top, and/or outer PCM layer are contemplated.

The second PCM in one or more arrangements has a properties group consisting of at least one of: a higher crystallization temperature (higher Tc) than the first PCM, a longer crystallization time than the first PCM, more easily forms voids (e.g., void forming) than the first PCM, and combinations thereof. The second PCM in an embodiment generally has higher electrical resistivity than the electrical resistivity of the first PCM layer in its crystalline state but not higher electrical resistivity than the electrical resistivity of first PCM in its amorphous state.

In an approach the first and second PCM are electrically conductive in its crystalline state and electrically resistive and/or insulating in its amorphous state and the second PCM has at least one of a higher crystallization temperature (higher Tc) than the first PCM, a longer crystallization time than the first PCM, and/or more easily forms voids (e.g., void forming) than the first PCM. The thicker, second, top, and/or outer PCM layer in an embodiment is formed of, from, and/or has second PCM that generally has higher electrical resistivity than the electrical resistivity of the crystalline first PCM but not higher electrical resistivity than the electrical resistivity of first PCM material in its amorphous state.

To form the PCM memory device from an initial state where the thin, first, bottom, and/or inner PCM layer is electrically conductive and the thicker, second, top, and/or outer PCM layer is also electrically conductive, a forming current pulse, preferably a SET pulse with an extended trailing edge, is provided by the bottom (heater) electrode to create a region, preferably a dome-shaped region (or void), in the thicker, second, top, and/or outer PCM layer that is electrically insulating and/or resistive. In an approach, once the electrically insulating and/or resistive dome is formed in the thicker, second, top and/or outer PCM layer, SET and RESET current pulses from the bottom (heater) electrode are configured to not change the electrical properties and/or state of the dome (e.g., the electrical insulating and/or resistive properties are maintained), and rather the SET and RESET current pulses from the bottom (heater) electrode preferably only switches the electrical properties, phase, and/or state of a region in the thin first, bottom, and/or inner PCM layer (e.g., low Tc PCM layer) between an amorphous (electrically insulating and/or resistive) state and a crystalline (electrically conductive) state through heating (melting) and/or cooling the localized region in that thin first, bottom, and/or inner PCM layer. That is, in an approach and/or configuration a RESET and/or SET pulse causes heat to be localized at the top of the heater electrode in the first PCM layer. In this manner, in an exemplary embodiment, the localized region in the first PCM layer that changes states between electrically conductive and electrically insulating and/or resistive forms the active region in the PCM memory structure.

For example, in an embodiment where the first PCM in the first thin PCM layer is crystalline and/or electrically conductive, preferably a low crystalline temperature (low Tc) PCM, and the second PCM material in the second, thicker PCM layer is an inverse PCM (iPCM) that is in an amorphous state where the iPCM is electrically conductive in the amorphous state and electrically resistive in the crystalline state, preferably a high crystalline temperature (high Tc) PCM (and/or a PCM with a long crystallization temperature or that easily forms voids), a forming current pulse, preferably a SET pulse with an extended trailing edge, is provided by the heater electrode to create a region, (e.g., dome shaped region) in the second PCM layer in the crystalline state that is electrically insulating and/or resistive. During resetting, since the crystallized region in the second PCM layer is electrically resistive compared to the crystallized first PCM layer and the amorphous portion(s) in the second PCM layer, the current flowing through the crystalline, electrically resistive region in the second PCM layer should be negligible. Heating preferably is contained mainly in the first PCM layer adjacent to and/or vertically above the heater electrode, and preferably within a region in the first PCM layer adjacent to and/or vertically above and aligned with the heater electrode. During setting, in an embodiment the crystallized electrically resistive and/or insulating region (e.g., dome-shaped region) in the second PCM layer remains due to the high crystallization temperature (high Tc) of the second PCM and first PCM in first PCM layer changes in the region above and/or adjacent the heater electrode from electrically resistive and amorphous to electrically conductive and crystalline.

In another embodiment where the first PCM, preferably having a low crystalline temperature (low Tc), in the first thin PCM layer is in a crystalline and/or electrically conductive state, and the second PCM material, preferably having a higher crystalline temperature (high Tc), in the second, thicker PCM layer that is compositionally different and also in the crystalline and/or electrically conductive state, a forming current pulse is provided by the heater electrode to create a region (e.g., a dome-shaped region, in the second PCM layer that is in an amorphous state that is electrically insulating and/or resistive. SET and RESET pulses switch, preferably only switch, the first PCM in the first PCM layer, more specifically in a configuration a first PCM region, preferably by heating localized to that first PCM layer, more specifically in a configuration to the first PCM region, between a crystalline state that is electrically conductive and an amorphous state that is electrically insulating and/or conductive.

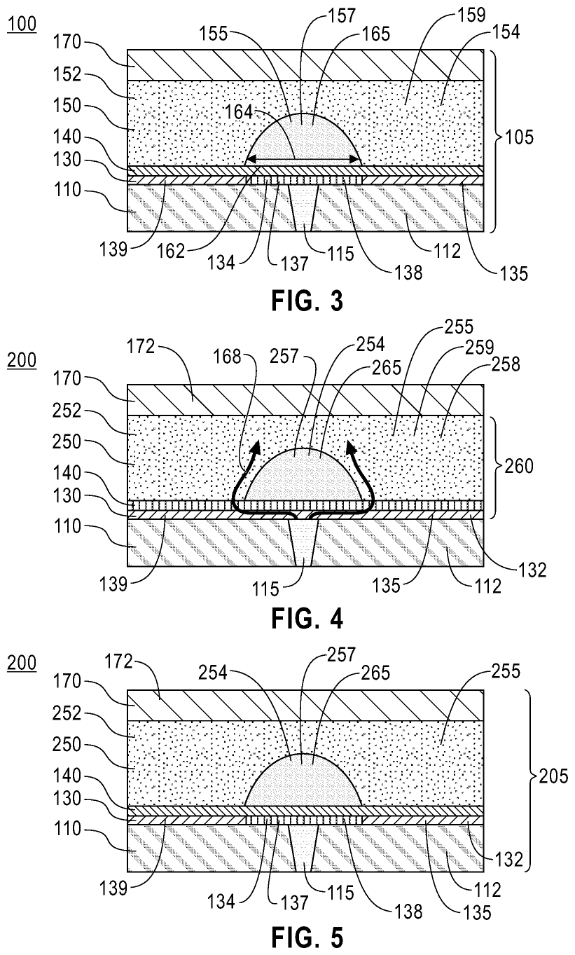

Turning to more specifics, FIGS. 2-3 illustrate cross-sectional views of an exemplary structure for a PCM memory device 100 that can be employed according to a first embodiment of the present application. The exemplary structure includes at least two PCM-containing layers 130, 150 separated by a barrier 140 preferably to inhibit and/or prevent intermixing between the two PCM containing layers 130, 150. The two PCM-containing layers 130, 150 with barrier layer 140 form a PCM sandwich layer 160. The first PCM containing layer 130 is formed of a first PCM 132 preferably of a different composition than second PCM 152 in second PCM containing layer 150.

The present application can work when a plurality of PCM-containing layers are present. The PCM memory device 100 can include one or more PCM-containing material stacks 105, each PCM-containing material stack 105 that is formed includes bottom electrode layer 110, phase change sandwich layer 160, and top electrode layer 170.

Each bottom electrode layer 110 is composed of a first electrically conductive electrode material 114 forming, in an approach, a bottom heater electrode 115. First or bottom electrode 115 in an embodiment has a width 116 of about 30 nm to about 50 nm, preferably about 40 nm, although other widths are contemplated for first or bottom electrode 115. Illustrative examples of first electrically conductive electrode materials 114 that can be used in providing electrode 115 in bottom electrode layer 110 include, but are not limited to, titanium nitride (TiN), tantalum nitride (TaN), ruthenium (Ru), cobalt (Co), nickel (Ni), copper (Cu), tungsten (W), tungsten nitride (WN), silver (Ag), platinum (Pt), palladium (Pd), aluminum (Al), or any suitable combination of those materials. Each bottom electrode layer 110 can include a single first electrically conductive electrode material 114 or a multilayered stack of first electrically conductive materials 114. Each bottom electrode layer 110 can be formed utilizing a deposition process such as, for example, chemical vapor deposition (CVD), plasma enhanced chemical vapor deposition (PECVD), physical vapor deposition (PECVD), atomic layer deposition (ALD), sputtering or plating.

Each bottom electrode layer 110 can have a thickness 118 from about 10 nm to about 200 nm; although other thicknesses are contemplated and can be used in the present application as the thickness of each bottom electrode layer 110. In an example embodiment, as shown in FIGS. 2-3, heater electrode 115 has a smaller diameter and/or width 116 than the width of bottom electrode layer 110, and preferably smaller diameter and/or width 116 than the width of PCM sandwich layer 160 and/or top electrode layer 170. In embodiments, each bottom electrode layer 110 can be composed of a compositionally same first electrically conductive electrode material 114. In other embodiments, compositionally different first electrically conductive electrode materials 114 can be employed.

Bottom electrode layer 110 in an embodiment includes a substrate 112, preferably a dielectric substrate 112 that contains the electrode 115 formed of first electrically conductive electrode material 114. A front-end-of-the-level (FEOL), a middle-of-the line (MOL) level and/or at least one interconnect level of a multilevel interconnect (i.e., back-end-of-the-line (BEOL) structure) can be included below bottom electrode layer 110 and/or substrate 112, for example in a layer below bottom electrode layer 110. So not to obscure the memory structure of the present application, the materials and techniques used in providing the FEOL, MOL and BEOL are not described or illustrated in the present application.

PCM sandwich layer 160 includes any material that undergoes a phase change from crystalline to amorphous or vice versa when energy is applied thereto whereby the electrical properties of the material also change. Such a material can be referred to herein as a phase change material (PCM). Generally, a PCM is electrically conductive in its crystalline state and electrically insulating and/or resistive in its amorphous state whereas an inverse PCM (iPCM) is also a PCM but has the opposite properties in its amorphous and crystalline states—electrically insulating and/or resistive in its crystalline state and electrically conductive in its amorphous state. More specifically, PCM sandwich layer 160 in an arrangement includes barrier layer 140 positioned between and/or separating a first, bottom, and/or inner PCM layer 130 formed of a first PCM 132 and a second, top, and/or outer PCM layer 150 formed of a second PCM 152 that is compositionally different than first PCM 132 in the first, bottom, and/or inner PCM layer 130. In an approach the barrier layer 140 is positioned adjacent to, above, over, directly over, and/or in contact with the first PCM layer 130, and in a further optional approach the barrier layer 140 is positioned adjacent to, below, directly below, and/or in contact with the second PCM layer 150.

In embodiments, the phase change material (PCM) that can be used in the present application for each of first PCM layer 130 and second PCM layer 150 includes a chalcogenide that contains an element from Group 16 (i.e., a chalcogen) of the Periodic Table of Elements and a more electropositive element. Examples of chalcogens that can be used as the phase change material include, but are not limited to, a GeSbTe alloy (GST), a SbTe alloy, or an InSe alloy. Other materials such as, for example, Cr₂Ge₂Te₆ (CrGeT), can also be used as the phase change material so long as this other material can retain separate amorphous and crystalline states. Alternatively, other suitable materials for the phase change material include Si—Sb—Te (silicon-antimony-tellurium) alloys, Ga—Sb—Te (gallium-antimony-tellurium) alloys, Ge—Bi—Te (germanium-bismuth-tellurium) alloys, In—Se (indium-tellurium) alloys, As—Sb—Te (arsenic-antimony-tellurium) alloys, Ag—In—Sb—Te (silver-indium-antimony-tellurium) alloys, Ge—In—Sb—Te alloys, Ge—Sb alloys, Sb—Te alloys, Si—Sb alloys, and combinations thereof. In some embodiments, the phase change material can further include nitrogen, carbon, and/or oxygen. In some embodiments, the phase change material can be doped with dielectric materials including but not limited to aluminum oxide (Al₂O₃), silicon oxide (SiO₂), tantalum oxide (Ta₂O₅), hafnium oxide (HfO₂), zirconium oxide (ZrO₂), cerium oxide (CeO₂), silicon nitride (SiN), silicon oxynitride (SiON), etc.

First PCM layer 130 is preferably relatively thin compared to the thickness of the second PCM layer 150. First PCM layer 130 in an embodiment can have a thickness 136 (See FIG. 10) preferably less than 15 nm, and preferably in the range of 2 nm to 15 nm; although other values for thickness 136 are contemplated and can be used in the present application as the thickness 136 of the first PCM containing layer 130. In embodiments, first PCM layer 130 can be composed of a compositionally same PCM (e.g., first PCM layer is homogenous). In other embodiments, compositionally different PCMs can be employed for first PCM layer 130.

In one or more embodiments, first PCM layer 130 is formed of first PCM material 132 having a relatively low crystalline temperature (low Tc) and/or a crystalline temperature that is relatively low compared to the crystallization temperature of second PCM material 152 forming second PCM layer 150. In an example embodiment, the crystallization temperature of the first PCM is about 150 degrees C. to about 180 degrees C.; although other crystallization temperatures are contemplated for first PCM. In a further example embodiment, first PCM has a crystallization temperature that is lower than the crystallization temperature of second PCM by 50 degrees C. or greater, although other temperature difference ranges between the crystallization temperature of the first PCM and second PCM are contemplated.

In the initial state as shown in FIG. 13, i.e., before a forming current pulse is applied to PCM sandwich 160, PCM-containing stack 105, and/or PCM memory structure or device 100, first PCM layer 130, preferably the entire first PCM layer 130 including the region above the electrode 115, is preferably in a crystalline state 135 that is electrically conductive (i.e., in a conductive state 139). That is, first PCM layer 110, in the embodiment of FIGS. 2-3, is provided, positioned, applied, deposited, and/or processed so that it is in a conductive (crystalline) state.

Second PCM layer 150 in the embodiment of FIGS. 2-3 is compositionally different than first PCM layer 130. In the embodiment of FIGS. 2-3 second PCM layer 150 contains and/or is formed of inverse PCM 152 (hereinafter “iPCM”) where the iPCM 152 is electrically conductive in its amorphous state and electrically resistive in its crystalline state. In a typical phase change material (“PCM”) the material (e.g., PCM material used in first PCM layer 130 of PCM memory structure 100) is electrically resistive in its amorphous state and electrically conductive in its crystalline state. Accordingly, iPCM 152 operates differently in its crystalline state and amorphous state than typical phase change materials (PCMs). In embodiments, the phase change material (PCM) that can be used in the present application for second iPCM layer 150 includes for example, Cr₂Ge₂Te₆ (CrGeT). Other iPCM materials are contemplated for use in second PCM layer 150. In the initial state as shown in FIG. 2, i.e., before a forming current pulse is applied to PCM sandwich 160, PCM-containing stack 105, and/or PCM memory structure or device 100, second PCM layer 150, preferably the entire second PCM layer 150 including the region above the electrode 115, is formed of iPCM 152 that is preferably in an amorphous state 154 that is electrically conductive (is in an electrically conductive state 159).

Second PCM layer 150 in an arrangement has a larger thickness 156 than the thickness 136 of the first PCM layer 130, and in an embodiment has a thickness 156 (See FIG. 10) in the range of 30 nm to 100 nm, and preferably a thickness 156 that is greater than about 60 nm; although other thicknesses 156 are contemplated and can be used in the present application as the thickness of the second PCM layer 150. Each of first, bottom, and/or inner PCM layer 130 and second, top, and/or outer PCM layer 150 can be formed utilizing a deposition process such as, for example, CVD, PECVD, PVD, or ALD.

The second iPCM 152 in second PCM layer 150 preferably has a high crystalline temperature (high Tc), and in an embodiment a crystallization temperature (Tc) at least higher than the crystallization temperature (Tc) of first PCM 132 in the first PCM layer 130. For example, crystallization temperature (Tc) of second iPCM 152 is 500 degrees C. or greater; although other crystallization temperatures for second iPCM 152 are contemplated, which could be lower than 500 degrees C. In a further example embodiment, the melting temperature (Tmelt) of second iPCM 152 is greater than 900 degrees C., preferably much greater than 900 degrees C., although other melting temperatures for second iPCM 152 are contemplated including temperatures less than 900 degrees C. In one or more embodiments, the iPCM 152 in second PCM layer 150 is at least one of a properties group consisting of PCM that is harder to crystallize than first PCM 132 of first PCM layer 130, has a higher crystallization temperature (Tc) than the crystallization temperature (Tc) of the first PCM 132 in first PCM layer 130, takes a longer time to crystallize than the first PCM 132 in the first PCM layer 130, and combinations thereof.

In the initial state as shown in FIG. 13, i.e., before a forming current pulse is applied to PCM sandwich 160, PCM-containing stack 105, and/or PCM memory structure or device 100, second PCM layer 150, preferably the entire second PCM layer 150 including the region above the electrode 115, is formed of iPCM 152 that is preferably in an amorphous state 154 that is electrically conductive (is in an electrically conductive state 159). As will be seen below, the higher crystallization temperature (high Tc), longer crystallization temperature, and/or the harder to crystallize state of the second iPCM 152 in second PCM layer 150 relative to first PCM 132 in first PCM layer 130 assists with forming, setting, and/or maintaining the electrically insulating and/or resistive region 165, which in the FIGS. 2-3 is created during a forming operation to be in a crystalline state 155 that is electrically insulating and/or resistive.

PCM memory device 100, and more particularly the PCM sandwich layer 160 includes a barrier layer 140. Barrier layer 140 in an embodiment is located adjacent to, above, over, directly over, and/or in contact with first PCM layer 130 and in an approach is positioned between first PCM layer 130 and second PCM layer 150. In a further embodiment, barrier layer 140 is positioned adjacent to, below, directly below, and/or in direct contact with second PCM layer 150. Barrier layer 140 preferably inhibits and/or prevents the intermixing of first PCM layer 130 and second PCM layer 150. In one or more embodiments, barrier layer 140 is relatively thin, and in an embodiment is thinner than the first PCM layer 130 and/or thinner than the second PCM layer 150. In a configuration, barrier layer 150 has a thickness 146 (Sec FIG. 10) in a range of 2 nm to 8 nm; although other thicknesses 146 are contemplated and can be used in the present application as the thickness 146 of the barrier layer 140.

In one or more arrangements, the barrier layer 140 is formed of, contains, and/or constitutes a non-phase change metal or semi-conductor, preferably a thin layer of non-phase change metal. Barrier layer 140 can be formed, contain, and/or constitute a metal and/or semiconducting material, and in an embodiment has similar or lower resistance than the first PCM layer 130 and/or the PCM 132 in first PCM layer 130. In one or more approaches barrier layer 140 can be formed of Tungsten (W), Tungsten Nitride (WN), Titanium dioxide (TiO2), and/or Tantalum Oxide (Ta2O5), although these are only example materials and other materials are contemplated for barrier layer 140. Barrier layer 140 in an example embodiment has high in-plane resistivity that inhibits and/or prevents intermixing between first PCM 132 in first PCM layer 130 and second (iPCM) 152 in second PCM layer 150. In an approach, barrier layer 140 can create additional thermal boundary resistance and can further potentially assist with and/or facilitate heat being contained in first PCM layer 130. Thermal boundary resistance between barrier layer 140 and first PCM layer 130 and between barrier layer 140 and second PCM layer 150 could further help localized heating. Barrier layer 140 in one or more configurations can also increase the forming voltage slightly, and additionally or alternatively can increase heating when forming the crystalline electrically resistive region 165 (e.g., dome-shaped region 165) which may reduce write current.

PCM memory device 100 and/or PCM containing stack 105 further includes a top electrode layer 170. Top electrode layer 170 is composed of a second electrically conductive electrode material 172 which preferably is compositionally different from the first electrically conductive electrode material 114 forming bottom electrode 115 in bottom electrode layer 110. Illustrative examples of second electrically conductive electrode materials 172 that can be used in providing top electrode layer 170 include one or more of the electrically conductive electrode materials mentioned above for the bottom electrode 115. In an exemplary embodiment top electrode layer 170 can be formed of titanium nitride. Top electrode layer 170 can include a single electrically conductive electrode material or a multilayered stack of second electrically conductive materials. Each top electrode layer 170 can be formed utilizing one of the deposition processes mentioned above in forming each bottom electrode layer 110 and bottom electrode 115. Each top electrode layer 170 can have a thickness 176 (see FIG. 10) from about 10 nm to about 100 nm; although other values for thickness 176 of top electrode layer 170 are contemplated and can be used in the present application as the thickness of the top electrode layer 170. In embodiments, each top electrode layer 170 can be composed of a compositionally same electrically conductive electrode material; but different from the first electrically conductive electrode material. In other embodiments, compositionally different second electrically conductive electrode materials can be employed, but different from the first electrically conductive electrode material.

Both first PCM layer 130 and second PCM layer 150 are initially conductive in the initial state of PCM memory structure 100 (see FIG. 13) where iPCM 152 in second layer 150 is amorphous as a result of, for example, the high crystallization temperature (high Tc) of iPCM 152 and through BEOL processing. An electrically insulating and/or resistive region 165, preferably dome shaped region 165, is formed in the second PCM layer 150 of PCM sandwich 160, PCM containing stack 105, and/or PCM memory device 100. That is, the second iPCM 152 in region 165 is configured to change from an electrically conductive amorphous state 154 as provided during manufacture of PCM memory structure 100 to the electrically insulating and/or resistive crystalline state 155. In an approach, an initialization current pulse, preferably a SET pulse with an extended trailing edge, is applied from bottom electrode 115 to the PCM sandwich layer 160 in its initial state where the first PCM layer 130 is crystalline and electrically conductive and the second PCM layer 150 is amorphous and also electrically conductive, which melts second PCM 152 (e.g., iPCM 152) in region 165 and melted second PCM 152 in region 165 is cooled in a manner that second PCM 152 in region 165 crystalizes to be in crystalline state 155 and becomes electrically insulating and/or resistive (in an electrically insulating and/or resistive state 157).

The electrically insulating and/or resistive region 165 in one or more embodiments preferably does not reach or come into contact with top electrode layer 170. In an embodiment, the region 165 preferably has a width 164 of about 100-120 nm at its base 162 where it is adjacent to and/or in contact with the barrier layer 140 and second PCM layer 150 preferably in an embodiment has a width of about 150 nm. Region 165 preferably has a height 166 that is about half the thickness 156 of the second PCM layer 150 and in embodiments has a height 166 greater than half the thickness 156 of the second PCM layer, and preferably has a height 166 about 30% to about 80% of the thickness 156 of the second PCM layer 150. In an approach, height 166 of region 165 is in the range of about 15 nm to about 60 nm.

FIG. 2 shows read current 168 with PCM memory device 100 in a SET state whereby read current 168 flows through crystalline, electrically conductive first PCM layer 130, through barrier layer 140, around electrically insulating and/or resistive region 165 in second PCM layer 150 and through amorphous and electrically conductive second iPCM 152 in first PCM region and/or portion 158 in second PCM layer 150 toward second electrode 170. In the SET state (shown in FIG. 2), the first PCM 132 in first PCM layer 130 is in the crystalline state 135 and is electrically conductive (in an electrically conductive state 139) and the second PCM 152 in second PCM layer 150 is in the crystalline state 155 in region 165 and is electrically insulating and/or resistive (in an electrically insulating and/or resistive state 157) but second iPCM 152 in second PCM layer 150 is in the amorphous state 154 and electrically conductive state 159 in region 158.

A RESET current pulse from first electrode 115 to PCM sandwich layer 160 in an embodiment melts first PCM 132 in first portion and/or region 138 of first layer 130 and melted first PCM portion 138 in an arrangement cools (e.g., undergoes a melt-quench current pulse) in a manner that changes and/or switches the crystalline conductive state 139 of first PCM portion 138 to amorphous state 134 that is electrically insulating and/or resistive (in an electrically insulating and/or resistive state 137). That is, heating occurs mainly in the first PCM layer 130 near the heater electrode 115 to cause a melt-quench cycle to the first PCM 132 in the amorphous state 134 in first PCM portion 138 while the iPCM 152 in region 165 remains in the crystalline, electrically resistive and/or insulating state 157. Preferably RESET current pulse only switches the electrical resistivity of PCM layer 130, including only first PCM 132 in first PCM portion 138 of first PCM layer 130 and in an embodiment accomplishes melting and forming the first PCM portion 138 in an amorphous and electrically insulating and/or resistive state 134/137 through localized heating. That is, SET and RESET pulses switch first PCM portion 138 in first PCM layer 130 between the crystalline conductive state 139 and amorphous insulating (resistive) state 137, and preferably the SET and RESET pulses only change the phase and electrical characteristics of first PCM portion 138 in first PCM layer 130 and the phase and electrical characteristics of regions 155 and 158 in the second PCM layer 150 are maintained.

FIGS. 4-5 illustrate cross-sectional views of an exemplary structure for a PCM memory device 200 that can be employed in accordance with an embodiment of the present application. The exemplary structure includes at least two PCM-containing layers 130, 250 separated by barrier layer 140 to prevent intermixing between the two PCM containing layers 130, 250. The first PCM containing layer 130 is preferably a different composition than second PCM containing layer 250. The present application can work when a plurality of PCM-containing layers are present. The PCM memory device 200 can include one or more PCM-containing material stacks 205, each PCM-containing material stack 205 that is formed preferably including bottom electrode layer 110, PCM sandwich layer 260, and top electrode layer 170.

The bottom electrode layer 110, the first, bottom, and/or inner PCM layer 130, the barrier layer 140, and the top electrode layer 170 in the embodiment of PCM memory device 200 in FIGS. 4-5 is the same as or substantially the same as bottom electrode layer 110, the first, bottom, and/or inner PCM layer 130, the barrier layer 140, and the top electrode layer 170 in the embodiment of PCM memory device 100 in FIGS. 2-3. In this manner the description of bottom electrode layer 110, first PCM layer 130, barrier layer 140 and top electrode layer 170 in FIGS. 2-3 applies to PCM memory device 200 in FIGS. 4-5. That is the first PCM layer 130 and barrier layer 140 fin the embodiment of FIGS. 4-5 functions and operates the same as or substantially the same as in the embodiment of FIGS. 2-3, including the additional thermal boundary resistance and associated properties discussed above in connection with barrier layer 140 in the embodiment of FIGS. 2-3. Second PCM layer 250 is compositionally different than first PCM layer 130 in PCM memory device 200 in FIGS. 4-5, resulting in a compositionally different PCM sandwich layer 260 than PCM sandwich layer 160 in FIGS. 2-3, a compositionally different PCM-containing stack 205 than PCM-containing stack 105 in FIGS. 2-3, and a compositionally different PCM memory device 200 than PCM memory device 100 in FIGS. 2-3.

In the embodiment of FIGS. 4-5 second PCM layer 250 contains, is formed of, and/or from second PCM 252 which is electrically conductive (in an electrically conductive state 259) in its crystalline state 255 and electrically insulating and/or resistive (in an electrically insulating and/or resistive state 257) in its amorphous state 254. Second PCM 252 preferably has at least one of a crystallization group consisting of: a higher crystallization temperature (higher Tc) than first PCM layer 130, a long or longer crystallization time (e.g., a longer time to crystallize than the first PCM 132 in the first PCM layer 130), and/or an easily void forming PCM (PCM that easily forms voids), and combinations thereof. Second PCM layer 250 in an arrangement is thicker than the thickness of the first PCM layer 130, and in an embodiment has a thickness 256 (See FIG. 10) in the range of 30 nm to 100 nm, and preferably a thickness 256 that is greater than about 60 nm; although other thicknesses 256 are contemplated and can be used in the present application as the thickness of the second PCM layer 250.

The PCM 252 in second PCM layer 250 preferably has a high crystalline temperature (high Tc) whereby the PCM crystallizes at a high temperature, and in an embodiment a crystalline temperature at least higher than the crystalline temperature of the PCM 132 in the first PCM layer 130. For example, the crystallization temperature of second PCM 252 could be about 200-350 degrees C., although other crystallization temperatures are contemplated for second PCM 252. In one or more embodiments, the PCM 252 in second PCM layer 250 has a long crystallization time and/or a longer crystallization time (e.g., it takes longer to crystalize) than PCM 132 in first PCM layer 130. For example, the time for second PCM 252 to crystalize in second PCM layer 250 could take anywhere from 200 ns to 5 μs, although other times for second PCM 252 to crystalize are contemplated. It can be appreciated that the high crystallization temperature (high Tc) and longer crystallization time for the second PCM 252 in second PCM layer 250 is relative to the first PCM 152 in first PCM layer 150. In a further embodiment, the PCM 252 in second PCM layer 250 easily forms voids (which are resistive in nature) when subject to multiple formation current pulses. As will be seen below, the high or higher crystallization temperature (high Tc), the long or longer crystallization time which makes the PCM 252 in second PCM layer 250 more difficult to crystallize assists with forming, setting, and/or maintaining the region 265, which in the FIGS. 4-5 is created during a forming operation to be in an amorphous resistive and/or insulating state 254.

A region 265, preferably dome shaped region 265, that is electrically insulating and/or resistive (in an electrically insulating and/or resistive state 257) is formed in the second PCM layer 250 of PCM sandwich 260, PCM containing stack 205, and/or PCM memory device 200. That is, the second PCM 252 in region 165 is configured to change from an electrically conductive state 259 that is crystalline (in a crystalline state 255) to electrically insulating and/or resistive state 257 that is amorphous (in an amorphous state 254). In FIGS. 4-5, during formation the second PCM layer 252 is provided, positioned, applied, deposited, and/or formed in an electrically conductive state 259 so the initial state of PCM memory device 200, PCM-containing stack 205, PCM sandwich layer 260 has second PCM layer 252 in an electrically conductive state 259 that is crystalline (in a crystalline state 255).

In an approach, an initialization current pulse is applied from bottom electrode 115 to the PCM sandwich layer 260 in its initial state where the first PCM layer 130 is crystalline and electrically conductive and the second PCM layer 250 is also crystalline and electrically conductive, which melts second PCM 252 in region 265 and melted second PCM 252 in region 265 is cooled in a manner that second PCM 252 in region 265 is in amorphous state 254 and becomes electrically insulating and/or resistive (is in an electrically insulating and/or resistive state 257). The insulating and/or resistive amorphous region 265 in one or more embodiments preferably does not reach or contact top electrode layer 170. In an embodiment, the region 265 has the dimensions as described above when discussing region 165.

FIG. 4 shows read current 168 with PCM memory device 200 in a SET state whereby read current 168 flows through crystalline conductive first PCM layer 130, through barrier layer 140, around insulating and/or resistive region 265 in second PCM layer 250 and through crystalline conductive second PCM 252 in region 258 in second PCM layer 250 toward second electrode 170. In the SET state, the first PCM 132 in first PCM layer 130 is in the crystalline state 135 and electrically conductive state 139 and the second PCM 252 in region 265 in second PCM layer 250 is in the amorphous state 254 and electrically insulating and/or resistive (in electrically insulating and/or resistive state 257) but in other region(s) 258 in second PCM 252 in second PCM layer 250 is in the electrically conductive state 259 and crystalline 255. A RESET current pulse from first electrode 115 to PCM sandwich layer 260 in an embodiment melts the first PCM 132 in first PCM portion 138 and melted first PCM portion 138 in an arrangement cools (e.g., undergoes a melt-quench current pulse) in a manner that changes and/or switches the crystalline state 135 and electrically conductive state 139 of first PCM portion 138 to amorphous state 134 that is electrically insulating and/or resistive (in an electrically insulating and/or resistive state 137) as shown in FIG. 5. Preferably RESET current pulse only switches the electrical resistivity of PCM layer 130, including only first PCM 132 in first PCM portion 138 of first PCM layer 130 and in an embodiment accomplishes melting and forming the amorphous electrically resistive first PCM portion 138 through localized heating. That is, SET and RESET pulses switch first PCM portion 138 in first PCM layer 130 between the crystalline conductive state 139 and amorphous insulating (resistive) state 137, and preferably the SET and RESET pulses only change the phase and electrical characteristics of first PCM portion 138 in first PCM layer 130 and the phase and electrical characteristics of regions 265 and 258 in the second PCM layer 250 are maintained.

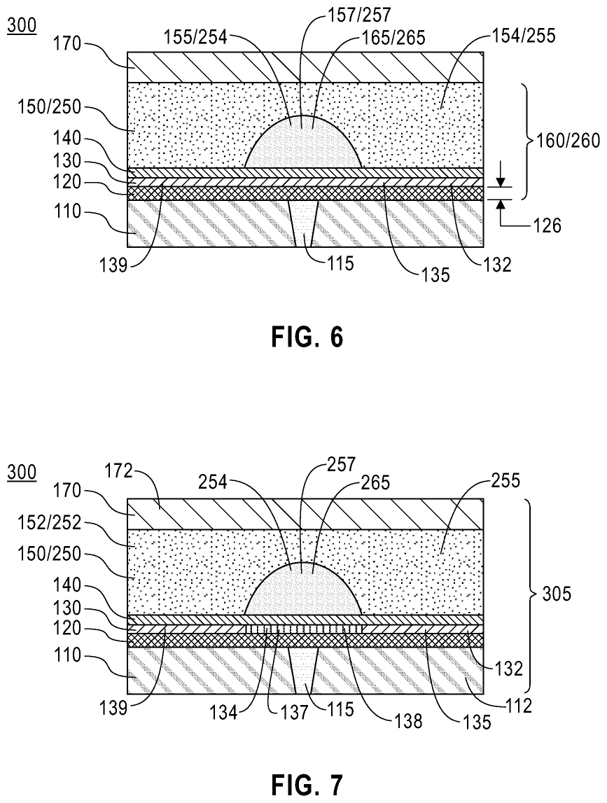

FIGS. 6-7 illustrate cross-sectional views of an exemplary structure for a PCM memory device 300 that can be employed according to additional embodiments of the present application. The exemplary structure 300 includes at least two PCM-containing layers separated by a barrier 140 preferably to inhibit and/or prevent intermixing between the two PCM containing layers. The first PCM layer 130 can be as described in FIGS. 2-5 while the second PCM layer can be the same or similar to the second PCM layer 150 as described in FIGS. 2-3 and/or second PCM layer 250 as described in FIGS. 4-5. The PCM memory device of FIGS. 6-7 can contain bottom electrode layer 110, top electrode layer 170, and PCM sandwich layer 160 and/or the PCM sandwich layer 260 as described respectively in FIGS. 2-5 with optional projection liner 120.

As shown in FIGS. 6-7 optional projection liner 120 is positioned above bottom electrode 110 and below top electrode 170. In an approach as shown in FIGS. 6-7 the optional projection liner 120 is positioned adjacent to, above, and/or in contact with bottom electrode 110 and is further positioned adjacent to, below, and/or in contact with first PCM layer 130. Other positions within PCM memory device are contemplated for projection liner 120. Projection liner 120 in an approach is formed of an electrically resistive non-switching material that preferably shunts amorphous state and reduce resistance drift. In an embodiment the projection liner 120 is non-PCM and when performing a melting operation in PCM memory structure 300 the projection liner should not melt. In an arrangement, projection liner 120 is slightly more resistive than first PCM 132 in first PCM layer 130. Projection liner has a thickness 126 that preferably ranges from about 2 nm to about 10 nm thick, although other values for thickness 126 are contemplated.

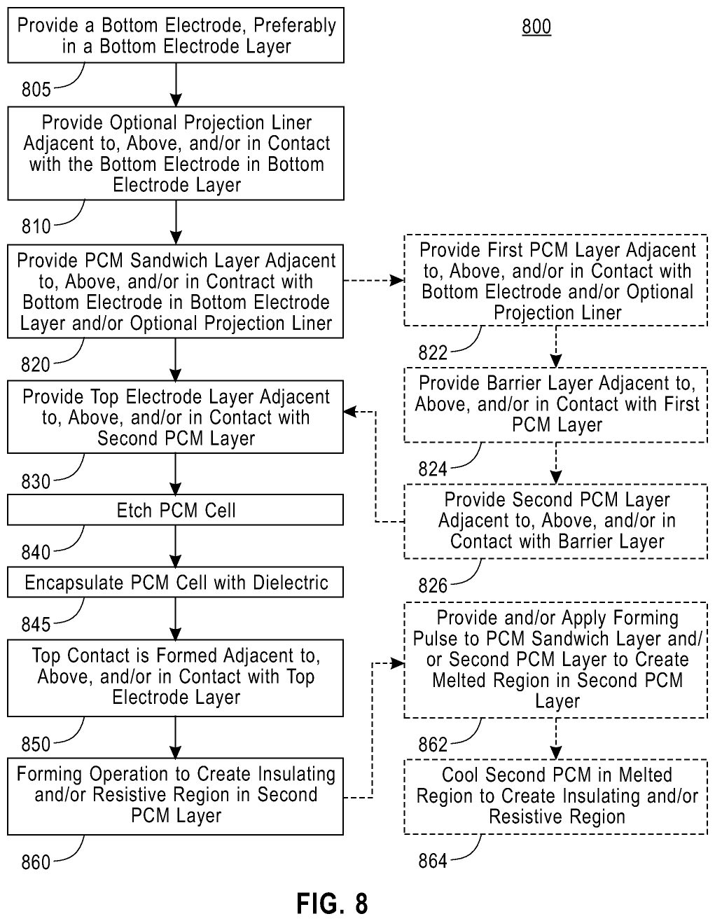

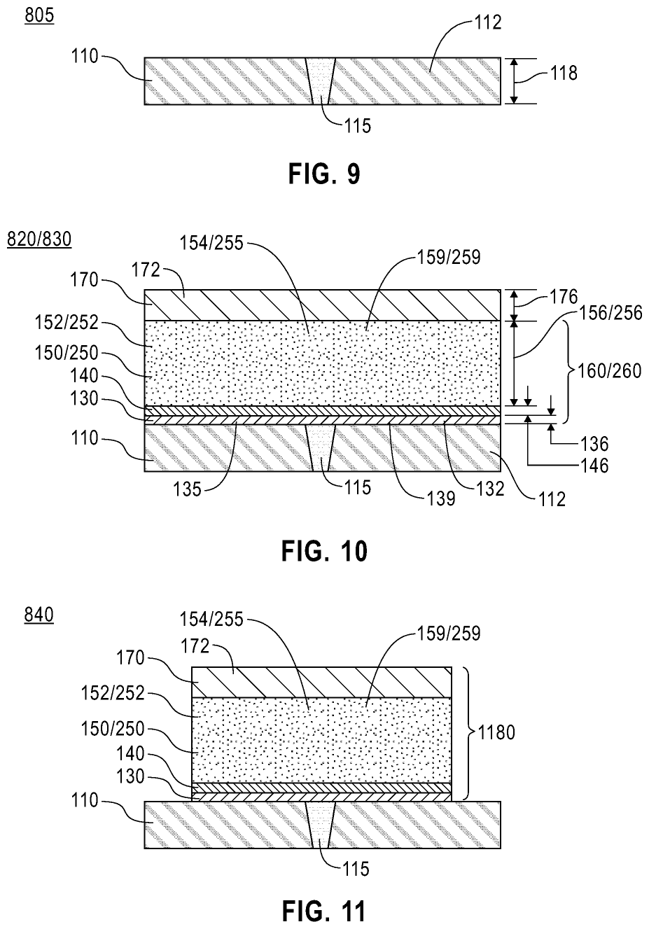

FIG. 8 is an exemplary flowchart in accordance with one embodiment describing a method 800 of making a PCM memory structure according to the disclosure that will be explained using the illustrations of FIGS. 9-15 showing the structure at various stages of method 800. While the method 800 is described for the sake of convenience and not with an intent of limiting the disclosure as comprising a series and/or a number of steps, it is to be understood that the process does not need to be performed as a series of steps and/or the steps do not need to be performed in the order shown and described with respect to FIG. 8, but the process may be integrated and/or one or more steps may be performed together, simultaneously, or the steps may be performed in the order disclosed or in an alternate order.

At 805, as shown in FIG. 9, a bottom and/or first electrode 115, preferably a heater electrode 115, is provided. Bottom electrode 115 in an embodiment, as shown in FIG. 9, is provided in a bottom electrode layer 110 and can include a substrate 112, where electrode 115 is preferably embedded and/or formed in substrate 112. Substrate 112 in an arrangement is a dielectric and can optional be formed of SiO2, SiN, etc. At 810 optional projection liner (e.g., projection liner 120) can be provided, positioned, applied, and/or deposited adjacent to, above, over, directly over, and/or in contact with bottom electrode layer 110 and/or bottom electrode 115.

At 820, as shown in FIG. 10, provide, position, and/or deposit PCM sandwich layer 160/260 adjacent, over, directly over, and/or in contact with bottom electrode 115, preferably adjacent to, over, directly over, and/or in contact with bottom electrode layer 110, and/or adjacent to, over, directly over, and/or in contact with optional projection liner (not shown). More specifically, process 820 can include at 822 providing, positioning, applying, and/or depositing first PCM layer 130, containing first PCM 132, adjacent to, over, directly over, and/or in contact with bottom electrode layer 110 and/or optional projection liner 120 (not shown). In an embodiment the first PCM layer 130 is provided, positioned, applied, and/or deposited as a thin layer and/or sheet, preferably about 2 nm to about 15 nm thick. The first PCM 132 in first PCM layer 130 is preferably low crystalline temperature (low Tc) PCM that preferably is provided, positioned, applied, and/or deposited in its crystalline state that is electrically conductive. Process 820 can include at 824 providing, positioning, applying, and/or depositing barrier layer 140 adjacent to, above, over, directly over, and/or in contact with first PCM layer 130. Barrier layer 140 preferably is conductive and/or semi-conductive and in an embodiment is a non-phase change metal. Barrier layer 140 preferably is thinner than first PCM layer 130 and in an arrangement is about 2 nm to about 8 nm thick.

Process 820 can include at 826 providing, positioning, applying, and/or depositing second PCM layer 150/250, containing second PCM 152/252, adjacent to, above, over, directly over, and/or in contact with barrier layer 140. In an embodiment, second PCM layer 150/250 is thicker than first PCM layer 130 and preferably is greater than 30 nm thick, preferably in a range of about 30 nm to about 100 nm thick. In an embodiment, second PCM 152, which includes iPCM 152 is provided, positioned, applied, and/or deposited, in the amorphous state 154 and is electrically conductive (in an electrically conductive state 159), while second PCM 252 is provided, positioned, and/or deposited in the crystalline state 255 and is also electrically conductive (in an electrically conductive state 259). Each of first, bottom, and/or inner PCM layer 130, barrier layer 140, and second, top, and/or outer PCM layer 150/250 can be formed utilizing a deposition process such as, for example, CVD, PECVD, PVD, or ALD.

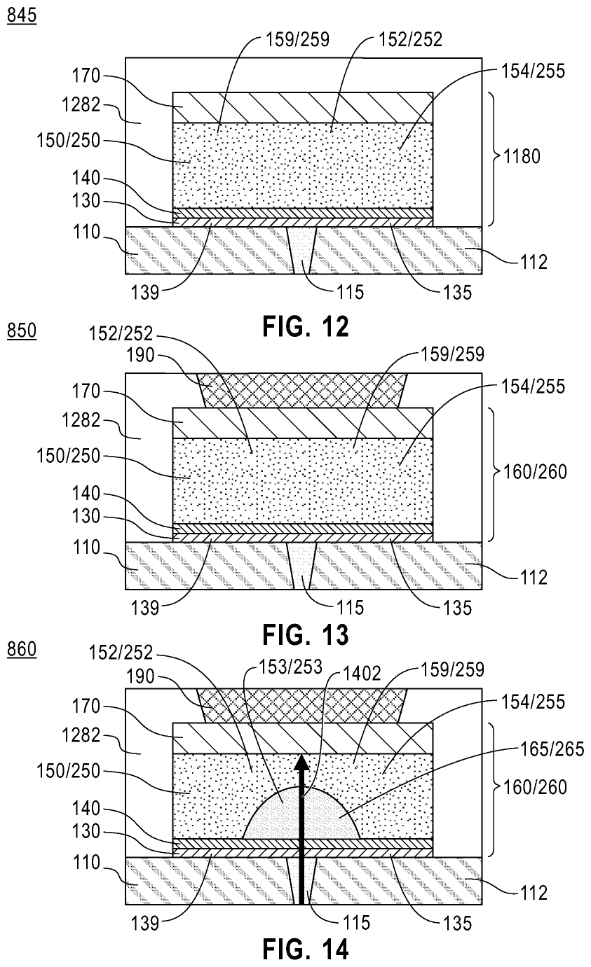

Process 800 can further include at 830 providing, positioning, applying, and/or depositing top electrode metal, including top electrode layer 170, adjacent to, above, over, directly over, and/or in contact with second PCM layer 150/250. At 840 PCM memory sub-cell 1180, as shown in FIG. 11, is etched. That is, the PCM memory sub-cell boundaries are formed by etching. At 845, the PCM memory sub-cell 1180 is encapsulated with dielectric 1282 as shown in FIG. 12, and in an embodiment encapsulation dielectric 1282, for example, Silicon Dioxide (SiO2) and/or Silicon Nitride (SiN), is deposited about PCM memory sub-cell 1080. At 850, top contact 190 is formed as shown in FIG. 13, where in an embodiment top contact 190, preferably a metal material 192, for example copper, is provided, positioned, applied, and/or deposited adjacent to, above, over, directly over, and/or in contact with top electrode layer 170.

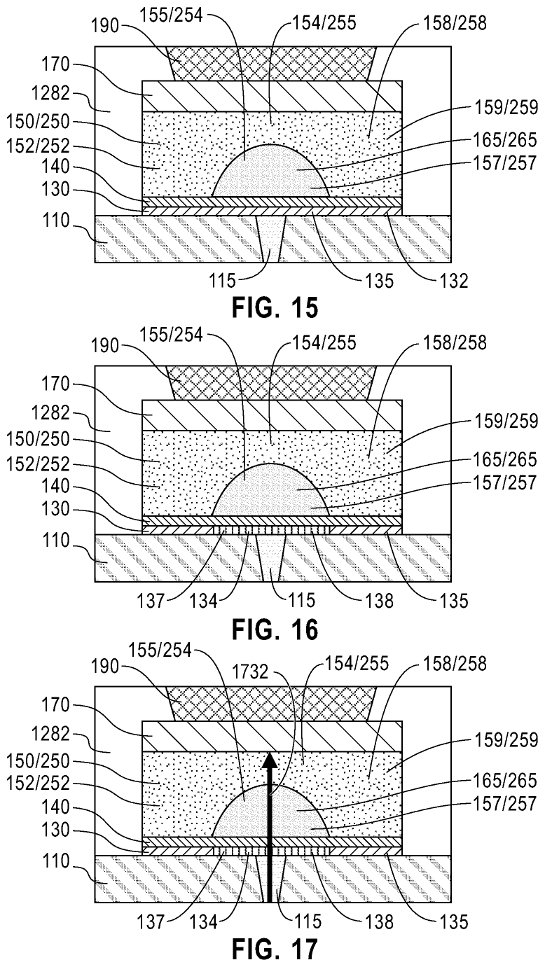

At 860 a forming operation is undertaken to form region 165/265, preferably dome shaped region 165/265, in second PCM layer 150/250 that is in an insulating and/or resistive state 157/257 as shown in FIG. 15. In an approach, process 860 can in an embodiment include at 862 providing and/or applying a forming current pulse 1402 as illustrated in FIG. 14 from bottom electrode 115 in bottom electrode layer 110 to PCM sandwich layer 160/260 and/or second PCM layer 150/250 that heats and melts second PCM 152/252 in region 165/265. That is, region 165/265 in second PCM layer 150/250 comprises second PCM 152/252 in a melted state 153/253 as shown in FIG. 14. Process 860 in an embodiment can further include at 864 cooling the second PCM 152/252 in region 165/265 in second layer 150/250 in a manner so that second PCM 152/252 in region 165/265 changes from a conductive state 159/259 (as seen in FIG. 13) to an insulating and resistive state 157/257 as shown in FIG. 15, while other portions 158/258 of second PCM layer 150/250 remain in a conductive state 159/259.

More specifically, at 860, in one or more embodiments, one or more forming current pulses 1402 as shown in FIG. 14 are provided and/or applied at 862 to PCM sandwich layer 160 and/or second PCM layer 150 and the second iPCM 152 in second PCM layer 150 that was in amorphous state 154 and electrically conductive (in an electrically conductive state 159) melts second iPCM 152 in region 165 so that second iPCM 152 is in a melted state 153 and melted iPCM 152 is thereafter at 864 cooled in a manner so that second iPCM 152 in region 165 in second PCM layer 150 attains a crystalline state 155 and is electrically insulating and resistive (is in an electrically insulating and/or resistive state 157) as shown in FIG. 15. In an example, a set pulse with an extended trailing edge is applied to generate an electrically resistive crystalline region 157 above heater electrode 115 while first PCM 152 in first PCM layer 150 remains crystalline and electrically conductive.

In a further embodiment, at 860, one or more forming current pulses 1402 are provided and/or applied at 862 as shown in FIG. 14 to PCM sandwich layer 260 and/or second PCM layer 250, and the second PCM 252 in second PCM layer 250 that was in crystalline state 255 and electrically conductive (in electrically conductive state 259) melts in region 265 so that second PCM 252 is in a melted state 253 and melted PCM 252 in region 265 is thereafter at 864 cooled in a manner so that second PCM 252 in region 265 in second PCM layer 250 attains an amorphous state 254 and is electrically insulating and resistive (in an electrically insulating and/or resistive state 257) as shown in FIG. 15. In an example, a set pulse with an extended trailing edge is applied to generate an electrically resistive amorphous region 257 above heater electrode 115 while first PCM 152 in first PCM layer 150 remains crystalline and electrically conductive.

Upon completion of the forming operation at 860, PCM memory structure 100/200 is in a formed or SET state as shown in FIG. 15 where first PCM layer 130 in PCM sandwich layer 160/260 is electrically conductive (and in, e.g., a crystalline state 135) and the second PCM layer 150/250 has region 165/265 that is in an electrically insulating and/or resistive state 157/257 and region 158/258 is in an electrically conductive state 159/259, where region 165/265 that is electrically insulating and/or resistive preferably is vertically aligned over the bottom electrode 115 where bottom electrode 115 in an embodiment has a width 116 that is smaller (is less wide) than the width 164/264 of region 165/265 that is in an electrically insulating and/or resistive state 157/257.

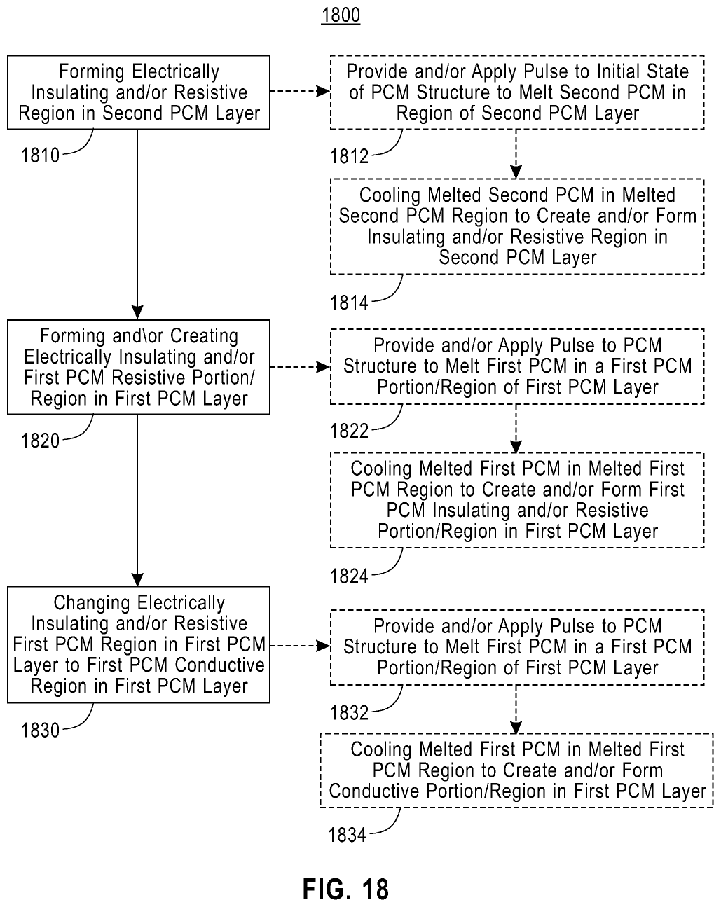

FIG. 18 is an exemplary flowchart in accordance with one embodiment describing a method 1800 of operating a PCM memory structure according to an embodiment of the disclosure that will be explained using the illustrations of FIGS. 13-17. While the method 1800 is described for the sake of convenience and not with an intent of limiting the disclosure as comprising a series and/or a number of steps, it is to be understood that the process does not need to be performed as a series of steps and/or the steps do not need to be performed in the order shown and described with respect to FIG. 18, but the process may be integrated and/or one or more steps may be performed together, simultaneously, or the steps may be performed in the order disclosed or in an alternate order.

In process 1800, from the initial state of PCM memory structure 100/200 as shown in FIG. 13, where the first PCM layer 130 has been provided, positioned, applied, and/or deposited in a crystalline state 135 and in the electrically conductive state 139 and the second PCM layer 150/250 has been provided, positioned, applied, and/or deposited in the electrically conductive state 159/259, create and/or form at 1810 region 165/265 in second PCM layer 150/250, preferably vertically aligned over bottom electrode 115, resulting in in PCM memory structure 100/200 in a SET or formed state (e.g., a formed PCM memory structure), as shown in FIG. 15.

More specifically, process 1810 in an approach includes, from the initial state of PCM memory structure 100/200 as shown in FIG. 13, where the first PCM layer 130 has been provided, positioned, applied, and/or deposited in an electrically conductive state 139 (preferably a crystalline state 135) and the second PCM layer 150/250 has been provided, positioned, applied, and/or deposited in the electrically conductive state 159/259, providing and/or applying at 1812 an electrical forming (e.g., current) pulse 1402 as shown in FIG. 14 from the bottom electrode 115 to the PCM sandwich layer 160/260 and/or second PCM layer 150/250 to melt second PCM 152/252 in region 165/265 to create and/or form second PCM 152/252 in a melted state 153/253 and/or create and/or form a void in region 165/265 in second PCM layer 150/250 as shown in FIG. 14. It can be appreciated that one or more forming pulses can be applied at 1812 to melt PCM 152/252 in region 165/165 and/or create a void at region 165/265. Process 1810 can also include at 1814 cooling melted second PCM 152/252 in region 165/265 in a manner to create an electrically insulating and/or resistive region 165/265, as shown in FIG. 15.

In method 1800, process 1810 in an approach can include, as shown in FIG. 13, in a PCM structure 100 in its initial state having a first PCM layer 130, containing first PCM 132, provided, positioned, applied, and/or deposited in an electrically conductive state 139 and crystalline state 135 and the second PCM layer 150, containing iPCM 152, provided, positioned, applied, and/or deposited in the amorphous state 154 and electrically conductive state 159, applying at 1812 an electrical forming (current) pulse 1402 as shown in FIG. 14 from the bottom electrode 115 to the PCM sandwich layer 160 and/or second PCM layer 150 to melt iPCM 152 in region 165 in second PCM layer 150 to form and/or create iPCM region 165 in a melted state 153 as shown in FIG. 14. Process 1810 can further include at 1814 cooling melted iPCM 152 in region 165 in a manner where region 165 is in a crystalline state 155 and is in an electrically insulating and/or resistive state 157, as shown at FIG. 15. During processes 1812 and 1814 potion 158 in second PCM layer 150 preferably attains, is in, results in, and/or remains in an amorphous state 154 and is electrically conductive (in an electrically conductive state 159).

Alternatively, process 1810 can include, in a PCM structure 200 in its initial state having a first PCM layer 130, containing first PCM 132, provided, positioned, applied, and/or deposited in an electrically conductive state 139 and crystalline state 135 and a the second PCM layer 250, containing PCM 252, provided, positioned, applied, and/or deposited in an electrically conductive state 259 and in crystalline state 255, applying at 1812 a forming pulse 1402 as shown in FIG. 14 from the bottom electrode 115 to the PCM sandwich layer 260 and/or second PCM layer 250 to melt PCM 252 in region 265 in second PCM layer 250 so that PCM region 265 is in a melted state 253 as shown in FIG. 14. Process 1810 can further include at 1814 cooling melted PCM 252 in region 265 in a manner where region 265 becomes electrically insulating and/or resistive (is in an electrically insulating and/or resistive state 257) and is in an amorphous state 254, as shown at FIG. 15. During processes 1812 and 1814 portion 258 in second PCM layer 250 preferably attains, is in, results in, and/or remains in a crystalline state 255 and is electrically conductive (is in conductive state 259).

It can be appreciated a forming pulse 1402, e.g., an electrical current pulse 1402, is applied at 1810 as shown in FIG. 14 from the bottom electrode 115 to PCM sandwich layer 160/260 and/or second PCM layer 150/250 to create and/or result in a region 165/265 in the second PCM layer 150/250 that is in an electrically insulating and/or resistive state 157/257, preferably a large electrically insulating and/or resistive dome region 165/265, as shown in FIG. 15, where in an approach region 165/265 that is in an electrically insulating and/or resistive state 157/257 can be a void (e.g., a hollow region). That is, at 1810, in a void forming approach, a forming pulse 1402, e.g., one or more forming pulses 1402, can be applied to PCM sandwich layer 160/260 and, in particular, to second PCM 152/252 in second layer 150/250 to create a void in region 165/265. Other portions 158/258 of second PCM layer 150/250, after application of electrical forming pulse 1402 at 1810, remain in the electrically conductive state 159/259 as shown in FIG. 15. The result of applying electrical forming pulse 1402 at 1810 to form a void 165/265 is PCM memory structure 100/200 in a SET or formed state (e.g., a formed PCM memory structure), as shown in FIG. 15, where the void is electrically insulating and/or resistive.

Process 1800 continues at 1820 where in formed PCM memory structure (e.g., state of PCM memory structure after creating insulating and/or resistive region 165/265 in the second PCM layer 150/250), first PCM portion 138 in first PCM layer 130 is formed and/or created that is electrically insulating and/or resistive (in electrically insulating and/or resistive state 137) as shown in FIG. 16. Process 1820 results in RESET PCM memory structure 100/200 as shown in FIG. 16. More specifically, in an approach, process 1820 includes at 1822 applying a RESET melting pulse to formed PCM memory structure, for example to PCM sandwich layer 160/260 and/or first PCM layer 130, to melt first PCM 132 in first PCM portion 138 to create and/or form melted first PCM portion 138 in first PCM layer 130 so that first PCM portion 138 is in a melted state 133 and preferably to melt only portion 138 in PCM sandwich layer 160/260. Preferably, at 1822 the insulating and/or resistive region 165/265 in second PCM layer 150/250 remains the same and does not melt. That is, in an approach, just first PCM 132 in first PCM portion 138 in first PCM layer 130 melts at 1822.

Process 1820 in an embodiment further includes at 1824 cooling the melted first PCM portion 138 of the first PCM layer 130 to form an amorphous electrically resistive first PCM portion 138 in first PCM layer 130 as shown in FIG. 16. That is, first PCM portion 138 becomes electrically insulating and/or resistive. In an embodiment a sharp quench can be applied at 1824 to cool the melted first PCM portion 138 of first PCM layer 130 to create and/or form amorphous electrically resistive first PCM portion 138. In an approach, during resetting, since the crystalline region 165/265 is electrically insulating and/or resistive compared to first PCM 152 in first PCM layer 130 and the adjacent portion(s) 158/258 the current flowing through the electrically insulating and/or resistive region 165/265 should be negligible and the heating preferably occurs in first PCM layer 130 near the heater electrode 115 to cause, assist with, and/or facilitate the melt-quench to amorphous first PCM 132 in first layer 130, while region 165/265 remains in its electrically insulating and/or resistive state 157/257. Process 1824 results in RESET PCM memory structure 100/200 having amorphous electrically insulating and/or resistive first CPM portion 138 as shown in FIG. 16.

Process 1800 continues at 1830 where amorphous electrically resistive (and/or insulting) first PCM portion 138 in first PCM layer 130 is processed to form a crystalline, electrically conductive PCM portion 138 as shown in FIG. 15. In an approach process 1830 includes at 1832 applying a melting pulse, for example an electrical current pulse 1732 to the RESET PCM memory structure, the PCM sandwich layer 160/260, and/or to first PCM layer 130 to melt (e.g., remelt) the amorphous electrically resistive (and/or insulating) first PCM portion 138 of the first PCM layer 130. Process 1830 can further include at 1834, cooling the PCM memory structure 100/200, PCM containing stack 105/205, PCM sandwich layer 160/260, first PCM layer 130, and/or melted first PCM portion 138 to create and/or form crystalline electrically conductive first PCM portion 138 as shown in FIG. 15. Process 1730 (including processes 1732 and 1734) form PCM memory structure in a SET state.

In one or more embodiments a memory structure is described that includes: a first electrode; a first phase change material (PCM) layer comprising a first PCM, the first PCM layer positioned above the first electrode; a second PCM layer located above the first PCM layer, the second PCM layer comprising a second PCM wherein the second PCM is compositionally different than the first PCM and has a properties group consisting of at least one of: a higher crystallization temperature than the first PCM, a longer crystallization time than the first PCM, more easily forms a void than the first PCM, and combinations thereof; a barrier layer positioned in between the first PCM layer and the second PCM layer wherein the barrier layer inhibits intermixing of the first PCM layer and the second PCM layer; and a second electrode positioned above the second PCM layer.

The memory structure in an arrangement can further include an electrically insulating and/or resistive region formed above the barrier layer in the second PCM layer, where in an approach the electrically insulating and/or resistive region is formed electrically or through process conditions. The electrically insulating and/or resistive region preferably is dome shaped and in a further embodiment is a hollow region forming a void above the barrier layer. In one or more embodiments, the barrier layer is electrically conductive and/or semiconductive. The barrier layer in an embodiment has high in-plane resistivity and preferably is formed of a non-phase change metal. In one or more approaches the barrier layer can be formed of Tungsten (W), Tungsten Nitride (WN), Titanium dioxide (TiO2), and/or Tantalum Oxide (Ta2O5), although these are only example materials and other materials are contemplated for the barrier layer. In an arrangement, the first PCM layer is thinner than the second PCM layer, preferably the first PCM layer is 15 nm thick or less. In a further arrangement, the second PCM layer has a thickness greater than 30 nm, the second PCM layer has a thickness between 50 nm and 70 nm. In yet a further example embodiment, the first PCM material includes a GeSbTe alloy (GST), a SbTe alloy, an InSe alloy, Cr2Ge2Te6 (CrGeT), Si—Sb—Te (silicon-antimony-tellurium) alloys, Ga—Sb—Te (gallium-antimony-tellurium) alloys, Ge—Bi—Te (germanium-bismuth-tellurium) alloys, In—Se (indium-tellurium) alloys, As—Sb—Te (arsenic-antimony-tellurium) alloys, Ag—In—Sb—Te (silver-indium-antimony-tellurium) alloys, Ge—In—Sb—Te alloys, Ge—Sb alloys, Sb—Te alloys, Si—Sb alloys, or any combination thereof.

The first PCM in one or more embodiments is electrically conductive in the crystalline state and electrically resistive in the amorphous state and the second PCM is an inverse PCM that is electrically resistive in the crystalline state and electrically conductive in the crystalline state. In an approach the inverse PCM is Cr2Ge2Te6 (CrGeT). The second PCM in one or more examples more easily forms a void than the first PCM forms a void by a void. In an embodiment, the second PCM includes a forming group consisting of at least one of: a lower heating temperature than the first PCM, a lower heating time than the first PCM, a lower voltage than the first PCM, a lower cycling threshold than the first PCM, and combinations thereof.

In one or more arrangements, the barrier layer is positioned in a first positional group consisting of at least one of: above, adjacent to, or in contact with at least a portion of the first PCM layer. And in yet further arrangements, the barrier layer is positioned in a second positional group consisting of: below, adjacent to, or in contact with at least a portion of the second PCM layer. The memory structure in one or more embodiments can optionally further include a protective liner positioned between the first electrode and the first PCM material, the protective liner comprising a resistive non-switching material to shunt the amorphous state and reduce resistive drift of the first PCM layer.

Also disclosed is a method of making a PCM memory structure that includes: providing a first electrode; providing a first phase change material (PCM) layer comprising a first PCM, the first PCM layer positioned above the first electrode; providing a second PCM layer located above the first PCM layer, the second PCM layer comprising a second PCM wherein the second PCM is compositionally different than the first PCM and has a properties group consisting of at least one of: a higher crystallization temperature than the first PCM, a longer crystallization time than the first PCM, more easily forms a void than the first PCM, and combinations thereof; a barrier layer positioned in between the first PCM layer and the second PCM layer wherein the barrier layer preferably inhibits intermixing of the first PCM layer and the second PCM layer; and providing a second electrode positioned above the second PCM layer. In one or more arrangements the method of making the PCM memory structure includes forming an electrically insulating and/or resistive region above the barrier layer in the second PCM layer, where in an approach the electrically insulating and/or resistive region is formed electrically or through process conditions. In one or more arrangements the method of making the PCM memory structure includes forming a hollow region or void as the electrically insulating and/or resistive region above the barrier layer in the second PCM layer, where in an approach the hollow region or void is formed electrically or through process conditions. The electrically insulating and/or resistive region preferably is dome shaped.

A method of operating a PCM memory structure is also described where the method includes: applying, in an initial state of a phase change material (PCM) memory structure comprising a first PCM layer comprising a first PCM in a crystalline state, a second PCM layer formed of a compositionally different PCM, and a barrier layer positioned between the first PCM layer and the second PCM layer, a forming current to create an insulating region in the second PCM layer to create a formed PCM memory structure. The method of operating the PCM memory structure can further include applying to the formed PCM memory structure a RESET melting current pulse that melts only a first portion of the first PCM in the first PCM layer, and in a further approach further includes cooling the melted first portion of the first PCM in the first PCM layer to form an amorphous first PCM portion in first PCM layer to create a RESET PCM memory structure. The method of operating the PCM memory structure in an embodiment can further include applying to the RESET PCM memory structure a SET melting current pulse that remelts the first PCM portion in the first PCM layer, and in a further embodiment further includes cooling the remelted first PCM portion of the first PCM layer to form a crystalline electrically conductive first PCM portion in the first PCM layer to create a SET PCM memory structure.

In one or more embodiments of the method of operating the PCM memory structure the first PCM is electrically conductive in the crystalline state and electrically resistive in the amorphous state and the second PCM is an inverse PCM that is electrically resistive in the crystalline state and electrically conductive in the amorphous state and a crystallization current, preferably large crystallization current, is applied to the PCM memory structure in its initial state to form a crystalline electrically resistive region in the second PCM layer to create the formed PCM memory structure. In an approach the crystalline resistive region in the second PCM layer in the formed PCM memory structure is dome shaped.

In an arrangement the method of operating the PCM memory structure further includes applying to the formed PCM memory structure a RESET melting current pulse to melt a first portion of the first PCM in the first PCM layer and quenching the melted first portion of the first PCM in the first PCM layer to form an amorphous first PCM portion in the first PCM layer to create a RESET PCM memory structure. The method of operating the PCM memory structure can further include applying to the RESET PCM memory structure a SET melting current pulse to melt the first portion of the first PCM in the first PCM layer and cooling the melted first portion of the first PCM in the first PCM layer to create a SET PCM memory state.

The method of operating the PCM structure includes in one or more embodiments, where the first PCM in the first PCM layer and the second PCM in the second PCM layer in the PCM memory structure are both crystalline in the initial state where the first PCM and second PCM are both electrically conductive in the crystalline state and electrically resistive in the amorphous state, applying the forming current to the PCM memory structure in its initial state and cooling conditions create the insulating region in the second PCM and a portion other than the insulating region in the second PCM layer that is conductive and crystalline to create the formed PCM memory structure. The method of operating the PCM memory structure can further include in an approach applying a RESET current pulse to the formed PCM memory structure to melt a first portion of first PCM in the first PCM layer and cooling the melted first portion of first PCM in the first PCM layer in a manner so that the first portion of the first PCM in the first PCM layer is in an amorphous electrically insulating state to create a RESET PCM memory structure. The method of operating the PCM memory structure can further include applying to the formed RESET PCM memory structure a crystallizing SET current pulse of low enough amplitude and duration to crystalize the first portion of first PCM in the first PCM layer to create a SET PCM memory structure.

While the present application has been particularly shown and described with respect to preferred embodiments thereof, it will be understood by those skilled in the art that the foregoing and other changes in forms and details may be made without departing from the spirit and scope of the present application. The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. It is therefore intended that the present application not be limited to the exact forms and details described and illustrated, but fall within the scope of the appended claims.

What is claimed is:

1. A memory structure comprising:
a first electrode;
a first phase change material (PCM) layer comprising a first PCM, the first PCM layer positioned above the first electrode;
a second PCM layer located above the first PCM layer, the second PCM layer comprising a second PCM wherein the second PCM is compositionally different than the first PCM and has a properties group consisting of at least one of: a higher crystallization temperature than the first PCM, a longer crystallization time than the first PCM, more easily forms a void than the first PCM, and combinations thereof;
a barrier layer positioned in between the first PCM layer and the second PCM layer wherein the barrier layer inhibits intermixing of the first PCM layer and the second PCM layer; and
a second electrode positioned above the second PCM layer.

2. The memory structure of claim 1, further comprising an electrically insulating region formed above the barrier layer in the second PCM layer.

3. The memory structure of claim 2, wherein the electrically insulating region is dome shaped.

4. The memory structure of claim 2, wherein the electrically insulating region is a hollow region forming a void above the barrier layer.

5. The memory structure of claim 1, wherein the barrier layer is the same thickness or thinner than the thickness of the first PCM layer and the barrier layer is at least one of a group consisting of: electrically conductive, semiconductive, and combinations thereof.

6. The memory structure of claim 1, wherein the first PCM layer is thinner than the second PCM layer.

7. The memory structure of claim 6, wherein the first PCM layer is 15 nm thick or less.

8. The memory structure of claim 7, wherein the second PCM layer has a thickness greater than 30 nm.

9. The memory structure of claim 1, wherein the first PCM material comprises a GeSbTe alloy (GST), a SbTe alloy, an InSe alloy, Cr₂Ge₂Te₆ (CrGeT), Si—Sb—Te (silicon-antimony-tellurium) alloys, Ga—Sb—Te (gallium-antimony-tellurium) alloys, Ge—Bi—Te (germanium-bismuth-tellurium) alloys, In—Se (indium-tellurium) alloys, As—Sb—Te (arsenic-antimony-tellurium) alloys, Ag—In—Sb—Te (silver-indium-antimony-tellurium) alloys, Ge—In—Sb—Te alloys, Ge—Sb alloys, Sb—Te alloys, Si—Sb alloys, or any combination thereof.

10. The memory structure of claim 1, wherein the first PCM is electrically conductive in the crystalline state and electrically resistive in the amorphous state and the second PCM is an inverse PCM that is electrically resistive in the crystalline state and electrically conductive in the crystalline state.

11. The memory structure of claim 10, wherein the inverse PCM is Cr₂Ge₂Te₆ (CrGeT).

12. The memory structure of claim 1, further comprising the barrier layer being positioned in a first positional group consisting of at least one of: over, adjacent to, or in contact with at least a portion of the first PCM layer and the barrier layer is further positioned in a second positional group consisting of: below, adjacent to, or in contact with at least a portion of the second PCM layer.

13. The memory structure of claim 1, further comprising a protective liner positioned between the first electrode and the first PCM material, the protective liner comprising a resistive non-switching material to shunt the amorphous state and reduce resistive drift of the first PCM layer.

14. A method of operating a PCM memory structure, the method comprising:
applying, in an initial state of a phase change material (PCM) memory structure comprising a first PCM layer comprising a first PCM in a crystalline state, a second PCM layer formed of a compositionally different PCM, and a barrier layer positioned between the first PCM layer and the second PCM layer, a forming current to create an electrically insulating region in the second PCM layer to create a formed PCM memory structure.

15. The method of claim 14, further comprising applying to the formed PCM memory structure a RESET melting current pulse that melts only a first portion of the first PCM in the first PCM layer.

16. The method of claim 15, further comprising cooling the melted first portion of the first PCM in the first PCM layer to form an amorphous first PCM portion in first PCM layer to create a RESET PCM memory structure.

17. The method of claim 16, further comprising applying to the RESET PCM memory structure a SET melting current pulse that remelts the first PCM portion in the first PCM layer.

18. The method of claim 17, further comprising cooling the remelted first PCM portion of the first PCM layer to form a crystalline electrically conductive first PCM portion in the first PCM layer to create a SET PCM memory structure.

19. A method of making a PCM memory structure comprising:
providing a first electrode;
providing a first phase change material (PCM) layer comprising a first PCM, the first PCM layer positioned over the first electrode;
providing a barrier layer over the first PCM layer;
providing a second PCM layer over the barrier layer, the second PCM layer comprising a second PCM wherein the second PCM is compositionally different than the first PCM and has a properties group consisting of at least one of: a higher crystallization temperature than the first PCM, a longer crystallization time than the first PCM, more easily forms voids than the first PCM, and combinations thereof;
providing a second electrode over the second PCM layer,
wherein the barrier layer is positioned between the first PCM layer and the second PCM layer.

20. The method of claim 19, further comprising forming an electrically insulating region above the barrier layer in the second PCM layer.
